(19) United States
(12) Patent Application Publication
(10) Pub. No.: US 2014/0205953 A1
(43) Pub. Date: Jul. 24, 2014

(54) METHOD FOR FORMING SEMICONDUCTOR DEVICE

(71) Applicant: UNITED MICROELECTRONICS CORP., Hsin-Chu City (TW)

(72) Inventors: Ching-Ling Lin, Kaohsiung City (TW); Po-Chao Tsao, New Taipei City (TW); Chia-Jui Liang, Tainan City (TW); En-Chiuan Liou, Tainan City (TW)

(73) Assignee: UNITED MICROELECTRONICS CORP., Hsin-Chu City (TW)

(21) Appl. No.: 13/747,421

(22) Filed: Jan. 22, 2013

(51) Int. Cl. G03F 7/20

(52) U.S. Cl. CPC G03F 7/20
USPC 430/312

(57) ABSTRACT

A method for forming a semiconductor device comprises the following steps: first, a substrate is provided, a first photo-etching process is carried out with a first photomask to form at least one device structure and a plurality of compensation structures, wherein the first photomask comprises at least one device pattern and a plurality of dummy patterns. A photoresist layer is then formed on the device structure and each compensation structures; a second photo-etching process is then carried out with a second photomask to remove each compensation structure.

### BACKGROUND OF THE INVENTION

1. Field of the Invention

The present invention relates to a semiconductor manufacturing process, specifically, a method for reducing the differences of pattern density of a photomask.

2. Description of the Prior Art

In semiconductor manufacturing processes, in order to transfer an integrated circuit layout onto a semiconductor wafer, the integrated circuit layout is first designed and formed as a photo-mask pattern. The photo-mask pattern is then proportionally transferred to a photoresist layer positioned on the semiconductor wafer.

As the design pattern of integrated circuit becomes smaller, and due to the resolution limit of the optical exposure tool, optical proximity effect will easily occur during the photolithographic process for transferring the photo-mask pattern with higher density. The optical proximity effect will cause defects when transferring the photo-mask pattern, such as right-angled corner rounding, line end shortening, and line width increasing/decreasing.

Therefore, in order to avoid the above-mentioned defects caused by the optical proximity effect, the semiconductor process uses a computer system to perform an optical proximity correction (OPC) method of the integrated circuit layout. The corrected integrated circuit layout is then designed as a photo-mask pattern and is formed on a surface of the photo-mask.

The prior art OPC method only uses one OPC model to correct the whole integrated circuit layout, and the different pattern densities in local regions of the photo-mask resulting in overexposure or underexposure are not taken into consideration. Furthermore, when a system on chip (SOC) is developed, many different kinds of semiconductor devices (such as memory, logic circuits, Input/Output, and central processing unit) are integrated and formed on one chip for substantially reducing the costs and improving speed. Therefore, the pattern density of integrated circuit layouts is very uneven in local regions, and the prior art OPC method is not applicable.

### SUMMARY OF THE INVENTION

In conventional semiconductor manufacturing process (which may comprise exposure, development and etching process), performing a photolithography process with only one photomask may influence the quality of the semiconductor, because of the differences in pattern density within a region.

The present invention provides a method for forming a semiconductor device, comprising the following steps: first, a substrate is provided, then, a first photo-etching process is carried out with a first photomask to form at least one device structure and a plurality of compensation structures, wherein the first photomask comprises at least one device pattern and a plurality of dummy patterns. A photoresist layer is then formed on the device structure and on each compensation structure, and a second photo-etching process is then carried out with a second photomask to remove each compensation structure.

The present invention further provides a method for forming a semiconductor device, comprising the following steps: first, a substrate is provided, then, a first photo-etching process is performed through a first photomask to form at least one device structure on the substrate; a photoresist layer is then formed on the device structure, and a second photo-etching process is performed through a second photomask to remove parts of the device structure.

The present invention provides a method for forming a semiconductor device. The feature of the present invention is that the photomask comprises a plurality of dummy patterns disposed around the device pattern to smoothen the differences in the pattern density of the photomask. Besides, the compensation structures will be removed during the second etching process so as to modify the edge of the device structure, improves the quality of the semiconductor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top-view diagram of the layout pattern according to the first preferred embodiment of the present invention.

FIG. 2 is a top-view diagram of the first photomask according to the first preferred embodiment of the present invention.

FIG. 3 is a top-view diagram of the second photomask according to the first preferred embodiment of the present invention.

FIGS. 4-9 are schematic, cross-sectional diagrams illustrating a method for forming a semiconductor device according to the first preferred embodiment of the invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and effects to be achieved.

Please note that the figures are only for illustration and the figures may not be to scale. The scale may be further modified according to different design considerations. Referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

FIG. 1 is a top-view diagram of the layout pattern, in accordance with the first preferred embodiment of the present invention. As shown in FIG. 1, a layout pattern 1 is provided, which comprises a plurality of patterns 2, 2A and 2B. The pattern 2 disposed in an isolated region 3, which has lower pattern density. The pattern 2A and 2B are disposed in a dense region 4, which has higher pattern density. The patterns 2, 2A and 2B are patterns which will be formed on a substrate or on a thin film in the following processes.

Because of the difference in pattern density within the isolated region 3 and the dense region 4, the quality of the pattern may be influenced if a photo-etching process with only one photomask is performed. Hence the present invention analyzes the layout pattern 1 with a computer system, and divides it into two pattern groups, which are the first layout pattern and the second layout pattern respectively. Afterward, the first layout pattern is output to a first photomask, and the second layout pattern is output to a second photomask respectively. Then, an exposure process, a development process and an etching process are then sequentially performed to the first photomask and the second photomask to form the layout pattern 1 on a substrate or on a thin film.

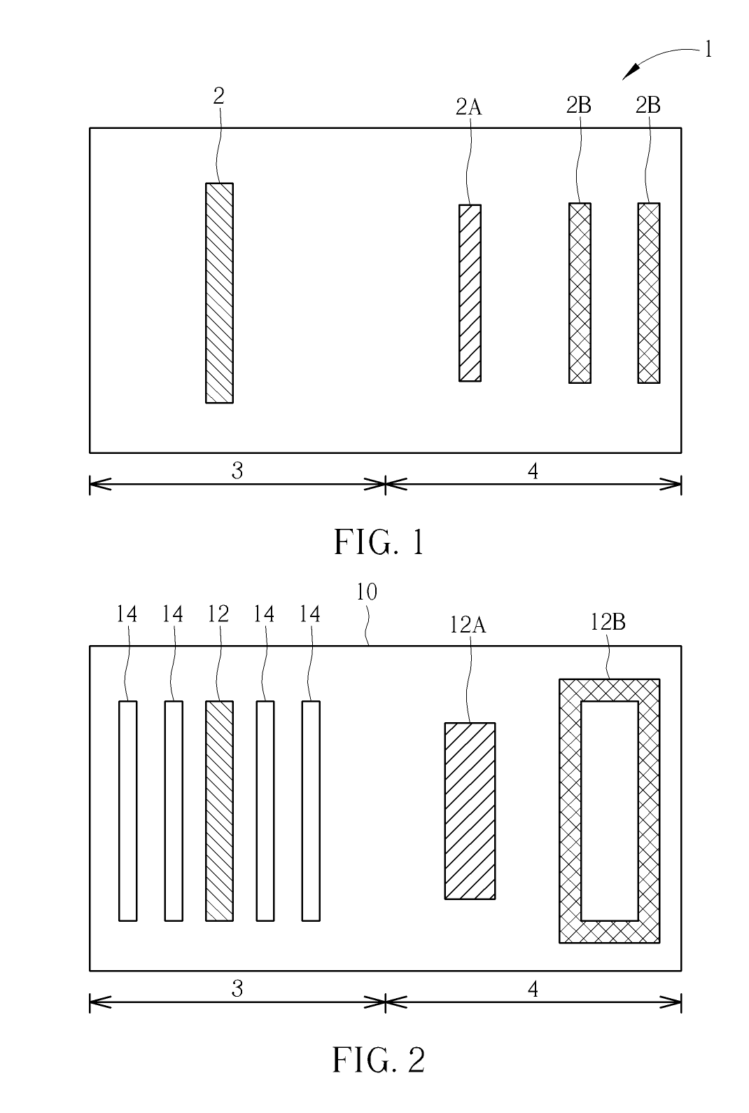

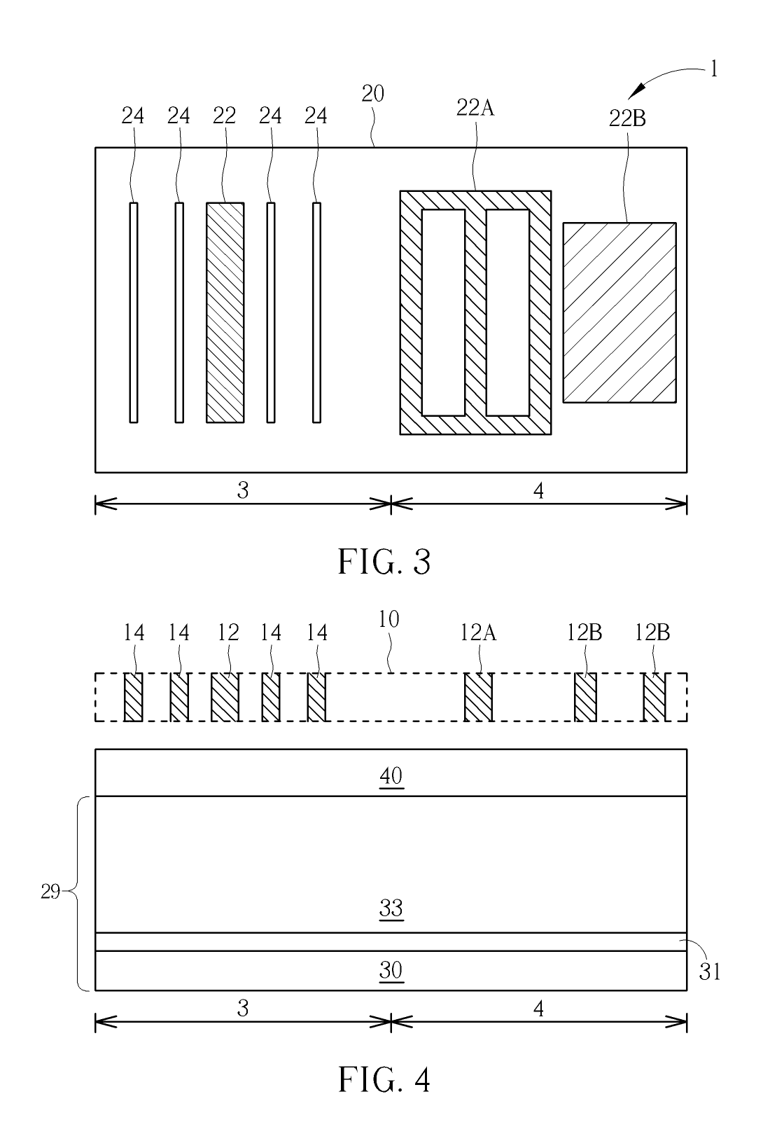

FIG. 2 is a top-view diagram of the first photomask in accordance with the first preferred embodiment of the present invention. FIG. 3 is a top-view diagram of the second photomask in accordance with the first preferred embodiment of the present invention. As shown in FIG. 2˜3, the first layout pattern and the second layout pattern are output to a first photomask 10 and a second photomask 20, wherein the first photomask 10 comprises device patterns 12, 12A, 12B and a plurality of dummy patterns 14, the second photomask 20 comprises device patterns 22, 22A, 22B and a plurality of nonprintable dummy pattern 24. Preferably but optionally, there are the plurality of nonprintable dummy pattern 24. In the following steps, a photo-etching process will be sequentially performed to the first photomask 10 and the second photomask 20 to transfer the patterns to a substrate (not shown).

The device patterns 12,12A and 12B on the first photomask 10 could be trace patterns, transistor patterns or other important device patterns. The location of each device pattern 12, 12A and 12B corresponds to the patterns 2, 2A and 2B of the layout pattern 1. The device pattern 12˜12B on the first photomask 10 can be transferred to a photoresist layer coated on a substrate (not shown) through an exposure process and a development process. Afterwards, an etching process is performed to transfer the pattern to a substrate or a thin film (not shown). However, in conventional semiconductor manufacturing processes, according to different layout pattern, some regions may have higher pattern densities, whereas some other regions may have lower pattern densities, which influence the quality of the semiconductor device after the photolithography process is performed. In this embodiment, the device pattern 12 is disposed within the isolated region 3, the device pattern 12A and the device pattern 12B are disposed within the dense region 4. To solve the issue mentioned above, the present invention further comprises a plurality of dummy patterns 14 disposed within the isolated region 3 on the first photomask 10, wherein each dummy pattern 14 may be a strip shaped or other shapes, disposed around the device pattern 12 or distributed over the blank region outside the device pattern 12 within the isolated region 3. Each dummy pattern 14 is used to reduce the difference in pattern density between the isolated region 3 and the dense region 4 of the first photomask 10 so as to influence the optical proximity effect occurring in a pattern transferring process.

It is worth noting that in this embodiment, the length and the width of the device pattern 12 and of each dummy pattern 14 are larger than a critical dimension, so the device patterns 12, 12A, 12B and each dummy pattern 14 on the first photomask 10 will be transferred to a substrate or a thin film during the photolithography process. However, on the second photomask 20, only the device patterns 22, 22A and 22B will be transferred to a substrate or a thin film, whereas the nonprintable dummy patterns 24 will not be transferred to the substrate or the thin film, because their length or width are smaller than the critical dimension. However, the nonprintable dummy patterns 24 also reduce the difference in pattern density of the second photomask 20. The critical dimension mentioned above generally is the minimum width that allows one pattern to be exposed and developed successfully. In other words, if the width or the length of one pattern is smaller than the critical dimension, then the pattern can not be transferred to the photoresist layer after the exposure process and the development process. Besides, in the present invention, the device patterns 12,12A and 12B on the first photomask 10 correspond to each device pattern 22, 22A and 22B on the second photomask 20, and the compensation structures 14 on the first photomask 10 correspond to the nonprintable dummy pattern 24 on the second photomask 20. It is worth noting that the compensation structures 14 on the first photomask 10 do not correspond to the device patterns 22, 22A or 22B on the second photomask 20, and that the compensation structures 14 which are formed on the substrate or on the thin film will not be removed in the following processes.

Please refer now to FIG. 4˜9, which are cross-sectional diagrams illustrating a method for forming a semiconductor device in accordance with the first preferred embodiment of the invention. As shown in FIG. 4, first, a substrate is provided, such as a silicon substrate, an epitaxial silicon substrate, a silicon germanium substrate, a bulk silicon substrate or a silicon carbide substrate. The present invention uses a silicon on insulator (SOI) substrate 29 as an example but it is not limited to, wherein the SOI substrate 29 comprises a substrate 30, an insulation layer 31 disposed on the substrate 30, and a silicon layer 33 disposed on the insulation layer 31. A first photoresist layer 40 is disposed on the SOI substrate 29. Then, the first photomask 10 shown in FIG. 1 is provided, on which a first photo-etching process will be performed. Therefore, as shown in FIG. 4, the first photomask 10 is disposed above the substrate 30 and the first photoresist layer 40, wherein the first photomask 10 comprises the device patterns 12, 12A, 12B and a plurality of dummy patterns 14. The device pattern 12 and each dummy pattern 14 are disposed within the isolated region 3, and the device pattern 12A and the device pattern 12B are disposed within the dense region 4.

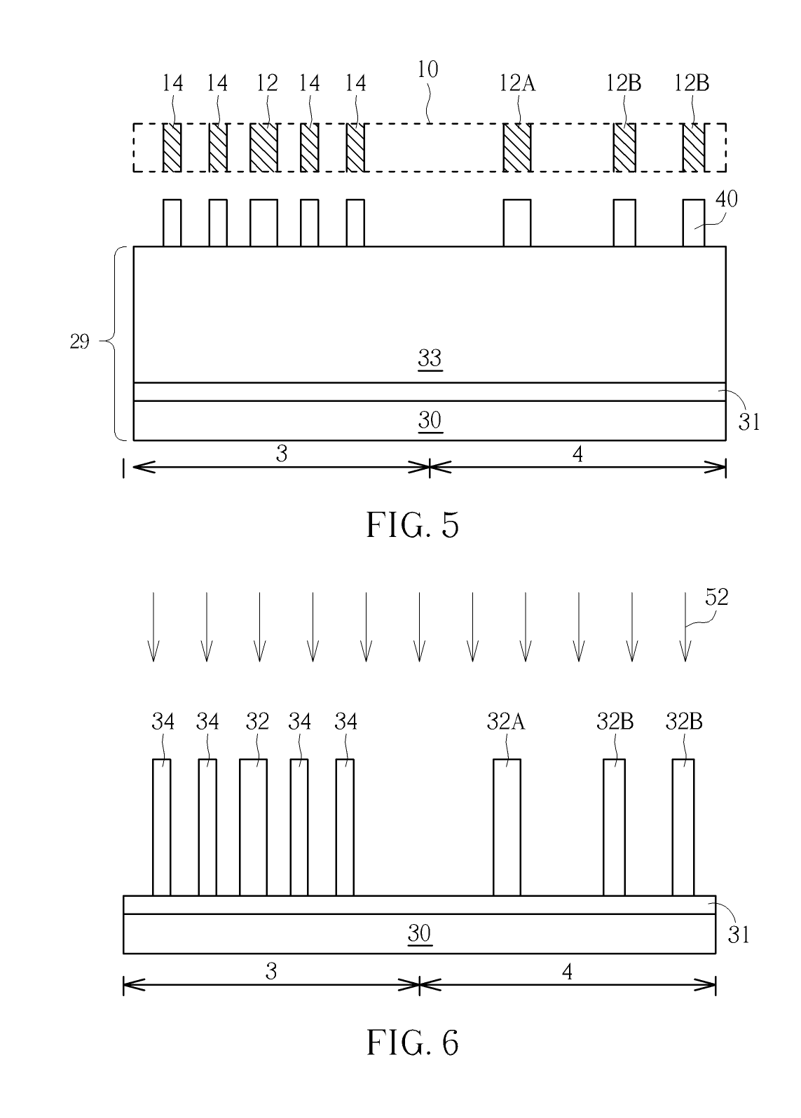

Then, as shown in FIG. 5, a first photo-etching process is performed on the first photomask 10, wherein the first photo-etching process at least includes sequentially performing an exposure process, a development process and an etching process. First, the exposure process and the development process are performed; the first photoresist layers 40 are patterned, wherein each patterned first photoresist layer 40 corresponds to each device pattern 12, 12A, 12B and each dummy pattern 14. Afterwards, an etching process 52 is then performed, as shown in FIG. 6, so as to transfer the pattern of the first photoresist layer 40 to the silicon layer 33 disposed under the first photoresist layer 40, and to form at least one the device structure 32, 32A, 32B and a plurality of compensation structures 34 on the substrate 30.

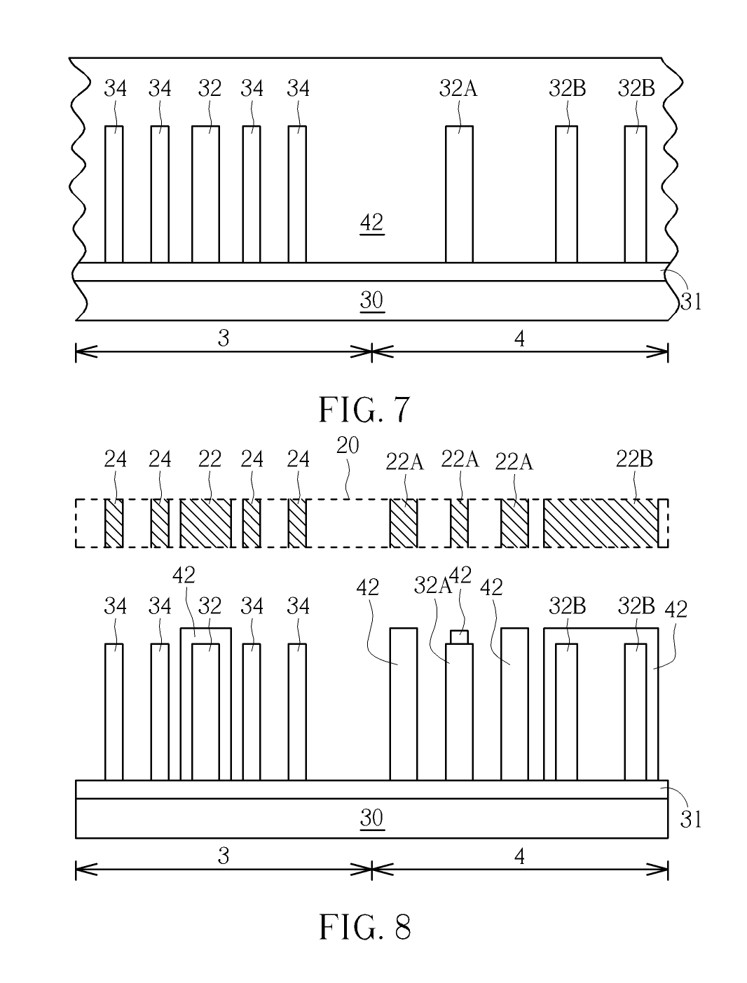

As shown in FIG. 7, a second photoresist layer 42 is formed on the device structures 32, 32A, and 32B and on each compensation structure 34. It is worth noting that in this embodiment, the second photoresist layer 42 contacts the device structures 32, 32A, 32B and each compensation structure 34 directly. In other words, there is no other layer disposed between the second photoresist layer 42 and the device structures 32, 32A, 32B, and the compensation structure 34.

As shown in FIG. 8, a second photo-etching process is then performed through the second photomask 20, which is similar to the first photo-etching process; the second photo-etching process comprises at least an exposure process, a development process and an etching process. The second photomask 20 comprises the device patterns 22, 22A, 22B and a plurality of nonprintable dummy patterns 24, the device pattern 22 and each nonprintable dummy pattern 24 are disposed within the isolated region 3, and the device pattern 22A and the device pattern 22B are disposed within the dense region 4. After the exposure process and the development process are performed, the second photoresist layer 42 is patterned. It is worth noting that since the length or the width of the nonprintable dummy pattern 24 is smaller than the critical dimension, hence those patterns will not be transferred to the second photoresist layer 42 during the exposure process and the development process. Only the device patterns 22, 22A and 22B have their widths larger than the critical dimension, and will be transferred to the second photoresist layer 42 successfully. Therefore, the presence of the nonprintable dummy pattern 24 is used to reduce the difference in pattern density on the second photomask 20, and it does not form needless pattern after the development process is performed. In addition, in one preferred embodiment of the present invention, the device pattern 22 on the second photomask 20 not only corresponds to the device pattern 12 on the first photomask 10, but the size of the device pattern 22 needs to be larger than the device pattern 12 and its alignment, in order to totally cover the device structure 32 (derived from the device pattern 12) by the patterned second photoresist layer 42 (derived from the device pattern 22) after the exposure process and the development process are performed.

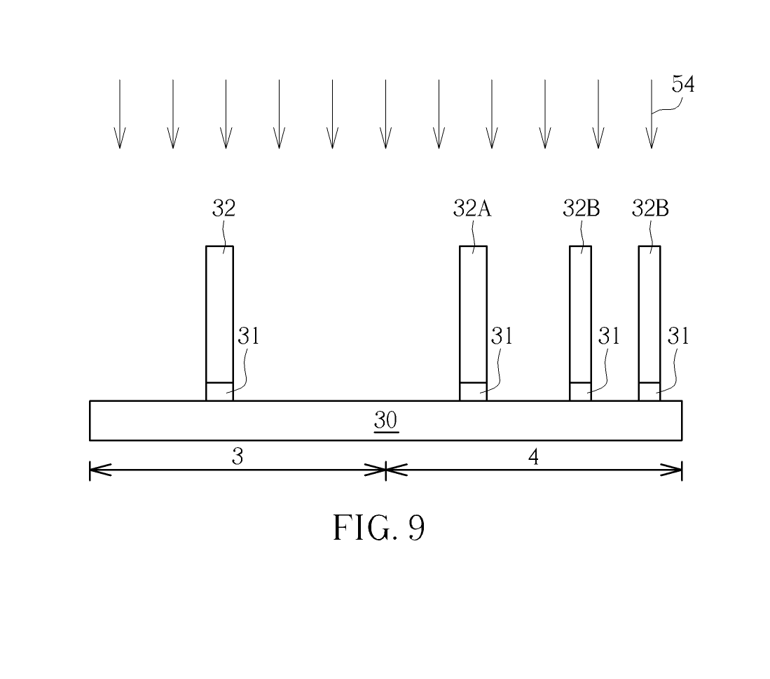

Finally, as shown in FIG. 9, the patterned second photoresist layer 42 is used as a hard mask to perform a second etching process 54, which removes parts of structure that are not covered by the second photoresist layer 42; the second photoresist layer 42 is then removed. In this case, the device structures 32, 32A and 32B will remain, and each compensation structure 34 will be removed, but it is not limited thereto. Depending on actual manufacturing demands, parts of the device structure 32 may be removed, or parts of the compensation structure 34 may be kept.

Besides, in order to further modify the edge of the device structures, such as removing the rough edges, or making the edge proximity to right angle, the present invention provides another embodiment, .t The steps are substantially similar to those of the first preferred embodiment, p. Please refer to the device structure 32A which is shown in FIGS. 4˜9, the same manufacturing steps with described in the first preferred embodiment are used to form at least one the device structure 32A on the SOI substrate 29, and a plurality of compensation structures (not shown) disposed beside the device structure 32A are selectively formed. Afterwards, each compensation structure is removed during the second etching process 54 with the second photomask 20. It is worth noting that, since the intermediate width of the device pattern 22A on the second photomask 20 is smaller than the device pattern 12A on the first photomask 10, hence the second photoresist layer 42 which covers the device structure 32A will expose parts of the device structure 32A, and those exposed device structures 32A will be removed during the second etching process 54, to especially modify the rough edges and thereby improving the quality of the semiconductor device.

In another embodiment of the present invention, in addition to modify the rough edges, the second photo-etching process may also cut the layout pattern. Please refer to the device structure 32B shown in FIGS. 4˜9, and also refer to FIGS. 1˜3, wherein the device pattern 12B (shown in FIG. 2) is a frame shaped pattern that will form a frame shaped device structure on the SOI substrate 29 after the first photo-etching process. But the device pattern 22B on the second photomask 20 (shown in FIG. 3) does not totally overlap the device pattern 12B, therefore, the final device structure 32B shown in FIG. 9 (please refer to the pattern 2B shown in FIG. 1 simultaneously) is constituted of two separated strip structures. In other words, the pattern 2B shown in FIG. 1 is the overlapping region between the device pattern 12B (shown in FIG. 2) and the device pattern 22B (shown in FIG. 3). Of course, the present invention is not limited thereto, and the layout pattern can be modified in accordance with the actual requirements.

The first etching process 52 and the second etching process 54 mentioned above are not limited to be a dry-etching or a wet-etching processes; in the etching step of the silicon layer 33, the etching process may be a dry etching process, using CF4, O2 and Ar, or a wet etching process, using dilute HF. The etching process is preferred to be an anisotropic etching process so as to protect the device structure disposed under the photoresist layer. In those embodiments mentioned above, except for using two photomasks sequentially performing photo-etching processes to achieve the optical proximity correction (OPC), other suitable OPC can selectively be performed to the device patterns 12˜12B, the device patterns 22˜22B, the dummy patterns 14 and the nonprintable dummy patterns 24.

The used photoresist of the present embodiment is a positive photoresist, with which transparent exposed areas are ultimately developed and etched away. The principles of the present invention also apply to negative photoresist systems, with which performing the reverse operation is possible, i.e, the transparent exposed areas that become exposed remain after the development process. The positive photoresists are most favored in today's advanced photolithography processes.

To summarize, the present invention provides a method for forming a semiconductor device, wherein a photomask comprises a plurality of dummy patterns disposed around a device pattern in order to reduce the differences in pattern density of the photomask. Besides, the compensation structures will be removed during the second etching process so as to modify the edge of the device structure, thereby improving the quality of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

1. A method for forming a semiconductor device, comprising the following steps:
providing a substrate;
performing a first photo-etching process with a first photomask to form at least one device structure and a plurality of compensation structures on the substrate, wherein the first photomask comprises at least one device pattern and a plurality of dummy patterns;
forming a photoresist layer on the device structure and on each compensation structures, wherein the photoresist layer contacts each device structure and each compensation structure directly; and
performing a second photo-etching process with a second photomask to remove each compensation structure.

2. (canceled)

3. The method of claim 1, wherein the device structure is formed according to the device pattern during the first photo-etching process.

4. The method of claim 1, wherein the compensation structure is formed according to the dummy pattern during the first photo-etching process.

5. The method of claim 1, wherein the second photo-etching removes parts of the device structure.

6. The method of claim 1, wherein the second photomask further comprises a plurality of nonprintable dummy patterns that are not transferred to the photoresist layer during the second photo-etching process.

7. The method of claim 1, wherein the location of each nonprintable dummy pattern corresponds to each compensation structure.

8. The method of claim 1, wherein the width of each nonprintable dummy pattern is smaller than a critical dimension.

9. The method of claim 1, wherein the plurality of dummy patterns is used to reduce the difference in pattern density of the first photo-mask pattern.

10. A method for forming a semiconductor device, comprising the following steps:
providing a substrate;
performing a first photo-etching process with a first photomask to form at least one device structure on the substrate;
forming a photoresist layer on the device structure, wherein the photoresist layer contacts each device structure directly; and
performing a second photo-etching process with a second photomask to remove parts of the device structure.

11. The method of claim 10, wherein the first photomask further comprises a plurality of dummy patterns.

12. The method of claim 11, further comprising forming a plurality of compensation structures on the substrate according to the dummy pattern during the first photo-etching process.

13. The method of claim 12, wherein the photoresist layer contacts each device structure and each compensation structure directly.

14. The method of claim 12, wherein the second photo-etching process removes each compensation structure.

15. The method of claim 10, wherein the second photomask further comprises a plurality of nonprintable dummy patterns that are not transferred to the photoresist layer during the second photo-etching process.

16. The method of claim 15, wherein the location of each nonprintable dummy pattern corresponds to each compensation structure.

17. The method of claim 15, wherein the width of each nonprintable dummy pattern is smaller than a critical dimension.
